(19) United States
(12) Patent Application Publication
(10) Pub. No.: US 2004/0154914 A1
(43) Pub. Date: Aug. 12, 2004

(54) Target for sputtering, sputtering device, and sputtering method

(75) Inventors: Kwan-Young Cho, Cheonan-city (KR); Dae-Yoep Park, Cheonan-city (KR); Sang-Ho Son, Cheonan-city (KR)

Correspondence Address: MacPherson Kwok Chen & Heid LLP, Suite 226, 1762 Technology Drive, San Jose, CA, 95110, US

(73) Assignee: SAMSUNG ELECTRONICS CO., LTD., Suwon-si (KR)

(21) Appl. No.: 10/745,942

(22) Filed: Dec. 24, 2003

(30) Foreign Application Priority Data
Dec. 26, 2002 (KR) 2002-0083955

(51) Int. Cl. C23C 14/35

(52) U.S. Cl. 204/192.17; 204/298.12; 204/192.12; 204/298.19; 204/298.2

(57) ABSTRACT

A sputtering conductor target is provided, which includes: a center portion; an edge portion around the center portion and having a thickness larger than the center portion; and an inclined portion disposed between the center portion and the edge portion and making an angle of about 30°-70° with a normal to a top surface of the edge portion.

### BACKGROUND OF THE INVENTION

(a) Field of the Invention

The present invention relates to a sputtering target, a sputtering device, and a sputtering method.

(b) Description of the Related Art

Generally, a semiconductor device is formed by depositing a plurality of conductive layers and a plurality of insulating layers and by patterning the deposited layers using photolithography, and the conductive layers are usually formed by sputtering.

The sputtering process for a conductive layer is performed in a sputter chamber in a vacuum state and includes following steps: bombarding particles are induced by using magnetic force to strike a conductor target; conductive particles are ejected from the target; and the ejected particles are directed to a substrate to form the conductive layer on the substrate.

The target is fixed to a plate during the sputtering process and a moving magnet cathode is provided for inducing the bombarding particles.

Since the magnet cathode goes and returns between two turning positions, where the magnet cathode spends a longer time than other positions, portions of the target disposed near the turning positions experience more corrosion than other portions. This non-uniform corrosion reduces the efficiency and the exchanging time of the target up to about 20%-30%.

### SUMMARY OF THE INVENTION

A motivation of the present invention is to provide a sputtering target, a sputtering device, and a sputtering method for solving the above-described disadvantages.

A sputtering conductor target is provided, which includes: a center portion; an edge portion around the center portion and having a thickness larger than the center portion; and an inclined portion disposed between the center portion and the edge portion and making an angle of about 30°-70° with a normal to a top surface of the edge portion.

The target may be mounted on a sputtering device such as a scanning type sputter chamber including a movable magnet cathode.

A sputtering device for a liquid crystal display substrate is provided, the device including: a support for supporting the substrate; a plate for mounting a conductor target including a center portion, an edge portion around the center portion and having a thickness larger than the center portion, and an inclined portion disposed between the center portion and the edge portion and making an angle of about 30°-70° with a normal to a top surface of the edge portion; and a (movable) magnet cathode located opposite the support with respect to the plate for controlling charged particles.

The substrate may be aligned such that an edge of the substrate is disposed opposite the inclined portion.

The target may include a plurality of separated portions having different thickness.

A method of sputter depositing a conductive layer on a liquid crystal display substrate using at least one magnet cathode is provided, the method includes: mounting a sputtering target including a center portion, an edge portion around the center portion and having a thickness larger than the center portion, and an inclined portion disposed between the center portion and the edge portion and making an angle of about 30°-70° with a normal to a top surface of the edge portion; disposing the substrate opposite the target; and sputtering the target onto the substrate.

A movable magnet cathode may be disposed opposite the substrate with respect to the target.

The substrate is preferably disposed such that an edge of the substrate is located at the inclined portion.

The target may include a plurality of separated portions having different thickness.

### BRIEF DESCRIPTION OF THE DRAWINGS

The present invention will become more apparent by describing embodiments thereof in detail with reference to the accompanying drawings in which:

FIG. 1A is a sectional view of a conductor target and a plate in a sputtering chamber according to an embodiment of the present invention;

FIG. 1B is a plan view of the conductor target shown in FIG. 1; and

FIG. 2 illustrates a sputter chamber used in a sputtering process using a conductor target according to an embodiment of the present invention.

### DETAILED DESCRITPION OF EMBODIMENTS

The present invention now will be described more fully hereinafter with reference to the accompanying drawings, in which preferred embodiments of the invention are shown. The present invention may, however, be embodied in many different forms and should not be construed as limited to the embodiments set forth herein.

In the drawings, the thickness of layers, films and regions are exaggerated for clarity. Like numerals refer to like elements throughout. It will be understood that when an element such as a layer, film, region or substrate is referred to as being “on” another element, it can be directly on the other element or intervening elements may also be present. In contrast, when an element is referred to as being “directly on” another element, there are no intervening elements present.

Now, sputtering targets according to embodiments of the present invention will be described with reference to the accompanying drawings.

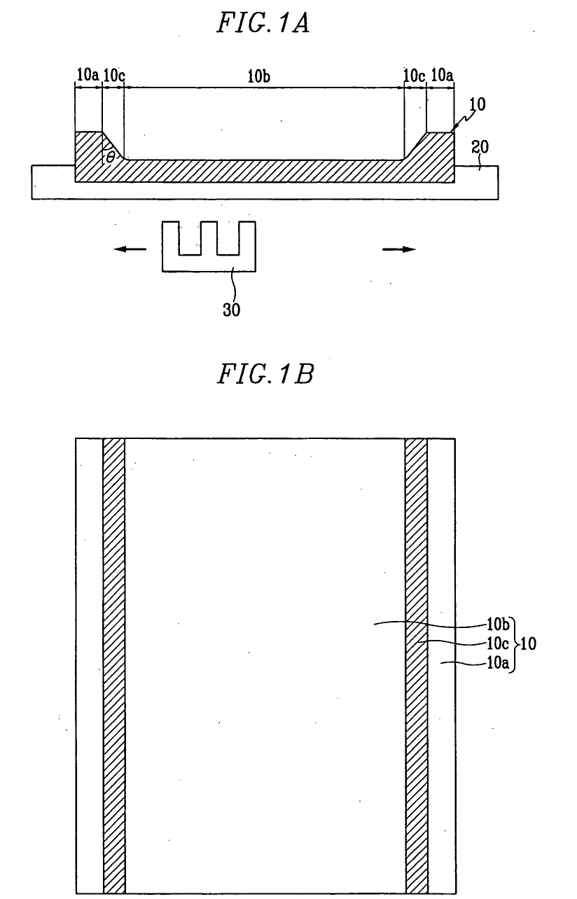

FIG. 1A is a sectional view of a conductor target and a plate in a sputtering chamber according to an embodiment of the present invention, and FIG. 1B is a plan view of the conductor target shown in FIG. 1.

A conductor target 10 for depositing a conductive layer by sputtering, as shown in FIG. 1A, includes a center portion 10b, a plurality of edge portions 10a thicker than the center portion 10b, and a plurality of inclined portions 10c located between the edge portions 10a and the center portion 10b and having a varying thickness. Each inclined portion 10c has an inclined surface extending from a top surface of an edge portion 10a to a top surface of the center portion 10b and making a smooth inclination angle θ with a normal to the top surface of the edge portion 10a. The inclination angle θ is preferably larger than about 10°, and more preferably, it ranges from about 30° to about 70°.

As shown in FIG. 1A, a sputtering device includes a plate 20 mounting the conductor target 10, a magnet cathode 30 disposed opposite the conductor target 10 with respect to the plate 20 for inducing bombarding particles. The magnet cathode 30, as indicated by arrows, moves between the edge portions 10a of the conductor target 10. A substrate (not shown) on which the sputtered particles are deposited is disposed such that the edges of the substrate are located at the inclined portions 10c.

Referring to FIG. 1B, the inclined portions 10c extend perpendicular to the moving direction of the magnet cathode 30.

Although the edge portions 10a of the conductor target 10, which are turning positions of the magnet cathode 30, are much corroded compared with other portions, the conductor target 10 is used for increased time since the edge portions 10a are thicker than other portions.

Since the inclination angle of the inclined portion 10c of the conductor target 10 is as smooth as 30°-70°, re-deposition of the sputtered particles on edges between the edge portions 10a and the inclined portions 10c of the sputtering target 10. In particular, the re-deposition of the sputtered particles results in black growths on an indium tin oxide (ITO) or indium zinc oxide (IZO) target to be sputtered to form transparent electrodes for a liquid crystal display (LCD), which can be prevented by using the sputtering target 10 having the above-describe structure.

Although the portions 10a, 10b and 10c of the sputtering target 10 shown in FIGS. 1A and 1B are incorporated into a body, they may be separately manufactured and separately mounted on the plate 20 for simplicity in manufacturing process.

When the substrate, particularly for an LCD, is large, for example, the substrate for an LCD has an area larger than about 680 mm×880 mm, a plurality of magnet cathodes 30 may be used and the number of the magnet cathodes 30 is changed if it is necessary.

Exemplary materials for the conductor target 10 are Al, Al alloy, Cr, Cr alloy, Mo, Mo alloy, Cu are Cu alloy as well as above-described ITO and IZO.

The thickness of the edge portions 10a of the conductor target 10 is about 10 mm, while the center portion 10b has the thickness of about 5 mm. The target 10 may be exchanged when a corrosion depth at the center portion 10b and the inclined portions 10c is about 1-2 mm and a corrosion depth at the edge portions 10b is about 7-8 mm.

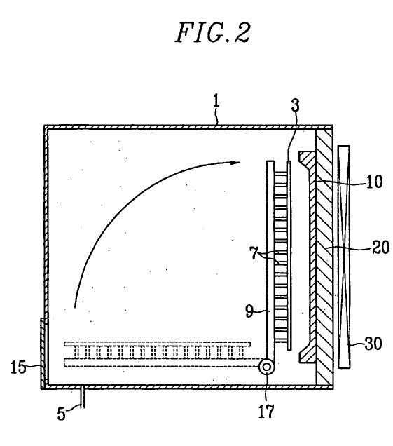

Now, a sputtering chamber according to an embodiment of the present invention is described in detail with reference to FIG. 2.

FIG. 2 illustrates a sputter chamber used in a sputtering process using a conductor target according to an embodiment of the present invention. The sputtering chamber shown in FIG. 2 may be used in a scanning type sputtering process for an LCD with a moving magnet cathode.

A sputtering device according to an embodiment of the present invention includes a transfer chamber (not shown) for transporting a substrate for an LCD in a vacuum state to be entered through a load-lock chamber (not shown), and a sputter chamber for sputter deposition of a conductive layer on the substrate transported from the transfer chamber.

As shown in FIG. 2, the sputter chamber 1 is evacuated for plasma discharge and supplied with Ar gas through a gas line 5. A support 9 including a plurality of pins 7 for supporting a substrate 3 and a plate 20 for mounting a conductor target 10 are provided in the sputter chamber 1.

An edge of the support 9 are hinged around a hinge axis 17 such that the support 9 receives the substrate 3 in a horizontal state entered into a gate 15 provided at the sputter chamber 1 and rotates the substrate 3 into a vertical state such that the substrate is parallel to the conductor target 10.

The plate 20 is fixed on a sidewall of the sputter chamber 1 such that the conductor target 10 mounted on the plate 20 is parallel to the substrate 3 of the support 9 when the support 9 is in the vertical state. A magnet cathode 30 is disposed opposite the substrate 3 with respect to the target 10 and the plate 20 and it moves in a direction parallel to the hinge axis 17.

When the plate 20 is powered and the magnet cathode 30 moves as shown in FIG. 1A, conductive particles are ejected from the conductor target 10 and deposited on the substrate 3 through a plasma disposed between the conductor target 10 and the substrate 3 according to the magnetic induction generated by the magnet cathode 30.

As described above, the thick edge portions 10a of the sputtering target 10 improve the efficiency of the conductor target 10, and the smoothly inclined portions 10c prevent re-deposition of the sputtered particles on the target as well as the black growths.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A sputtering conductor target to be mounted on a sputter chamber for sputter deposition, the target comprising:
a center portion;
an edge portion around the center portion and having a thickness larger than the center portion; and
an inclined portion disposed between the center portion and the edge portion and making an angle of about 30°-70° with a normal to a top surface of the edge portion.

2. The target of claim 1, wherein the sputter chamber comprises a scanning type scanning chamber including a movable magnet cathode.

3. A sputtering device for a liquid crystal display substrate, the device comprising:
a support for supporting the substrate;
a plate for mounting a conductor target including a center portion, an edge portion around the center portion and having a thickness larger than the center portion, and an inclined portion disposed between the center portion and the edge portion and making an angle of about 30°-70° with a normal to a top surface of the edge portion; and
a magnet cathode located opposite the support with respect to the plate for controlling charged particles.

4. The device of claim 3, wherein the magnet cathode is movable.

5. The device of claim 3, wherein the substrate is aligned such that an edge of the substrate is disposed opposite the inclined portion.

6. The device of claim 3, wherein the target comprises a plurality of separated portions having different thickness.

7. A method of sputter depositing a conductive layer on a liquid crystal display substrate using at least one magnet cathode, the method comprising:
mounting a sputtering target including a center portion, an edge portion around the center portion and having a thickness larger than the center portion, and an inclined portion disposed between the center portion and the edge portion and making an angle of about 30°-70° with a normal to a top surface of the edge portion;
disposing the substrate opposite the target; and
sputtering the target onto the substrate.

8. The method of claim 7, further comprising:
disposing a movable magnet cathode opposite the substrate with respect to the target.

9. The method of claim 7, wherein the substrate is disposed such that an edge of the substrate is located at the inclined portion.

10. The method of claim 4, wherein the target comprises a plurality of separated portions having different thickness.
